(19) United States
(12) Patent Application Publication
(10) Pub. No.: US 2006/0138604 A1
(43) Pub. Date: Jun. 29, 2006

(54) Low charging dielectric for capacitive MEMS devices and method of making same

(75) Inventors: Christopher F. Kirby, Gambrills, MD (US); Robert J. Horner, Severn, MD (US); Harlan C. Cramer, Columbia, MD (US); Robert S. Howell, Silver Spring, MD (US); Robert C. Tranchini, Ellicott City, MD (US); Gregory C. DeSalvo, Joppa, MD (US); Gilbert E. Dix, Annapolis, MD (US); Jeremiah J. Horner, Glen Burnie, MD (US)

Correspondence Address: ROTHWELL, FIGG, ERNST & MANBECK, P.C., 1425 K STREET, N.W., SUITE 800, WASHINGTON, DC, 20005, US

(73) Assignee: NORTHROP GRUMMAN CORPORATION, Los Angles, CA (US)

(21) Appl. No.: 11/020,270

(22) Filed: Dec. 27, 2004

(51) Int. Cl. H01L 23/58

(52) U.S. Cl. 257/640

(57) ABSTRACT

An improved dielectric suitable for use in electronic and micro-electromechanical (MEMS) components. The dielectric includes silicon nitride having a percentage of Si:H bonds greater than a percentage of N:H bonds, in order to reduce the level of charge trapping of the silicon nitride.

### BACKGROUND OF THE INVENTION

1. Field of the Invention

The present invention is directed to micro-electromechanical systems. More particularly, the present invention relates to a method of depositing a low charging dielectric for capacitive micro-electromechanical systems.

2. Description of the Related Art

Dielectrics may be used in many different applications—as an insulator or barrier layer in semiconductor devices, as an active element of a micro-electromechanical systems (MEMS) device, etc. When a dielectric traps a charge therein, it can diminish the dielectrics desired functionality.

MEMS have been developed for use in a number of electronic devices and components, such as phase shifters, tunable filters, and resonators. MEMS switches operate through the electrostatic actuation of a beam to achieve physical contact with an electrode. An exemplary capacitive MEMS switch is shown in FIG. 1. MEMS device 100 includes a switch beam 1 and a bottom electrode 3 separated by an air-gap 2. The electrode 3 has a dielectric layer 4 formed on top of it. A charge can be delivered to the electrode 3, which causes the beam 1 to make contact with the dielectric layer 4 to close the switch. To open the switch, the charge is removed from the electrode and the beam 1 moves away from the electrode 3.

Loss of bandwidth of switch 100 is defined by the RF coupling through the dielectric layer 4. The down capacitance of the switch 100 is determined based on the thickness and dielectric constant of the dielectric layer 4. The choice of dielectric, however, is constrained by many of the switch properties such as the actuation voltage, as this sets the field across the dielectric. The field strength must remain below the breakdown voltage of the dielectric. Silicon nitride is a compound that has been found to have a relatively high dielectric constant (κ˜7) and a relatively high dielectric strength (˜6000 kV/cm). Based on its combination of properties, silicon nitride is used extensively in MEMS devices.

It is known to use plasma enhanced chemical vapor deposition (PECVD) to deposit these nitrides as the dielectric layer in MEMS devices because of the ability to deposit these films at relatively low temperatures (˜200-300° C.), which is compatible with the materials and substrates used to fabricate MEMS devices.

Capacitive MEMS switches utilizing silicon nitride as a dielectric layer have shown failure mechanisms associated with the charging of the dielectric. This failure mechanism manifests itself as an increased “open state” capacitance resulting from the accumulation of charge trapped within the dielectric film. This trapped charge can exert enough force on the beam to decrease the air-gap between the beam and the dielectric or to keep the keep the beam in contact with the dielectric in the “open” state (i.e., after the charge has been removed from electrode 3).

FIG. 2 illustrates the increase in the “open” state capacitance of a MEMS switch as a function of time. The degradation of the “open” capacitance can be interpreted to result from the accumulation of trapped charge in the dielectric film, which exerts enough force on the beam to decrease the air-gap between the beam and the dielectric.

Silicon nitride films are capable of storing charge for extended periods of time. Charge can be trapped in both shallow surface states and deep bulk traps. The density of surface states can be impacted by material properties, deposition conditions, and environmental conditions such as subsequent processing steps, humidity, oxidation, and surface contamination. The bulk traps can be impacted by both the deposition conditions and the material properties of the dielectric. As shown in FIG. 2, over time, the trapped charge affects the opening and closing of the switch causing it to close erroneously or to fail to open properly.

The behavior of the dielectric in the MEMS switch is difficult to determine because mechanical, electrical, material, and environmental complications can be associated with testing a complete MEMS switch.

Thus, there is a continued need for new and improved dielectric layers for use in MEMS devices and methods for testing and fabricating the same.

### SUMMARY OF THE INVENTION

According to a preferred embodiment of the present invention, a dielectric film is provided for use in MEMS devices. The dielectric is compatible with MEMS fabrication techniques, decreases the rate of charge accumulation in the bulk dielectric by greater than 95% and increases switch lifetime reliability by 40 times relative to standard silicon nitride films.

According to another embodiment of the present invention, a test structure is provided for monitoring the impact of the MEMS switch fabrication process on charge accumulation in the nitride films. The test structure includes an M-I-S (Metal-Insulator-Semiconductor) structure.

According to another embodiment of the present invention, a method of fabricating a MEMS device is provided. The method includes a step of depositing a dielectric film on an electrode of the MEMS device. An amount of trapped charge within the dielectric film is determined during the depositing step. At least one process parameter is adjusted in the deposition step in order to reduce the amount of trapped charge within the dielectric film.

According to another embodiment of the present invention, a method is provided for determining an amount of trapped charge in a dielectric film of a MEMS device. The method includes a step of depositing a dielectric film on a silicon wafer. The dielectric film is deposited under the same conditions as the dielectric film of the MEMS device. A metal layer is deposited on top of the dielectric film. The resulting M-I-S structure is biased with a bias voltage. The flatband voltage and capacitance of the M-I-S structure is measured. The amount of trapped charge is calculated based on the flatband voltage and capacitance measured.

According to another embodiment of the present invention, a method is provided for fabricating a capacitive MEMS switch having a dielectric film. The method includes a step for fabricating a M-I-S structure on a dielectric film; a step for determining an amount of trapped charge in the dielectric film; a step for determining optimum process parameters associated with depositing the dielectric film to minimize the amount of trapped charge in the dielectric film; and a step for fabricating the MEMS switch utilizing the optimum process parameters to deposit the dielectric film.

Two strong correlations were discovered relative to the observed molecular bonding and the charging behavior of nitrides. The desirable low charging behavior of a nitride is believed to correspond to a high number of Si:Si bonding, as well as a large ratio of Si:H bonds compared to N:H bonds. Improved nitrides have Si:H/N:H ratios preferably greater than 1, and more preferably greater than 3; and extinction coefficients (at 248 nm) preferably greater than 0.06, and more preferably greater than 0.1.

Further applications and advantages of various embodiments of the invention are discussed below with reference to the drawing figures.

### BRIEF DESCRIPTION OF THE DRAWINGS

FIG. 1 is a side view of a prior art MEMS capacitive switch;

FIG. 2 is a graph of capacitance versus time for a MEMS switch, showing the open and closed positions;

FIG. 3 is a graph showing the trapped charge versus time for the prior art device and for an embodiment of the present invention;

FIG. 4 is a graph illustrating MEMS reliability for an embodiment of the present invention;

FIG. 5 is a graph of trapped charge versus bias time for dielectric films; and

FIG. 6 is a side view of an exemplary MIS capacitor;

FIG. 7 is a graph of the reflective spectrum of several generic silicon nitride films;

FIG. 8 is a table showing the thickness of a number test films;

FIG. 9 is a wafer mapping of an exemplary wafer having a nitride deposited thereon;

FIG. 10 is a graph illustrating deposition rates of test nitrides;

FIG. 11 is a graph of trapped extinction coefficients and refractive index;

FIG. 12 is a graph of the refractive index for test nitrides;

FIG. 13 is a graph of the extinction coefficient for test nitrides;

FIG. 14 is a table of extinction coefficients and refractive index for test nitrides;

FIG. 15 is a graph showing the extinction coefficient at 248 nm for the test nitrides;

FIG. 16 is a graph showing the logarithmic correlation between the band gap energy and the extinction coefficient at 248 nm;

FIG. 17 is a table showing the wavenumber at which certain molecular bonds absorb energy;

FIG. 18 shows the IR spectrum for the L1-STD nitride;

FIG. 19 is a summary of the results of IR measurements for the test nitrides;

FIG. 20 is a graph showing bond concentrations for the test nitrides;

FIG. 21 is a graph showing negative voltage lobe I-V sweep for each test nitride;

FIG. 22 is an illustration of C-V curves obtained from flatband measurement;

FIG. 23 is a graph showing trapped charge for selected test nitrides; and

FIG. 24 is a graph showing trapped charge versus time.

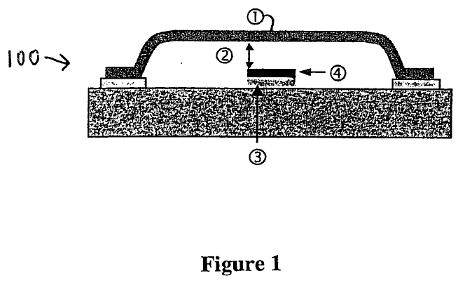

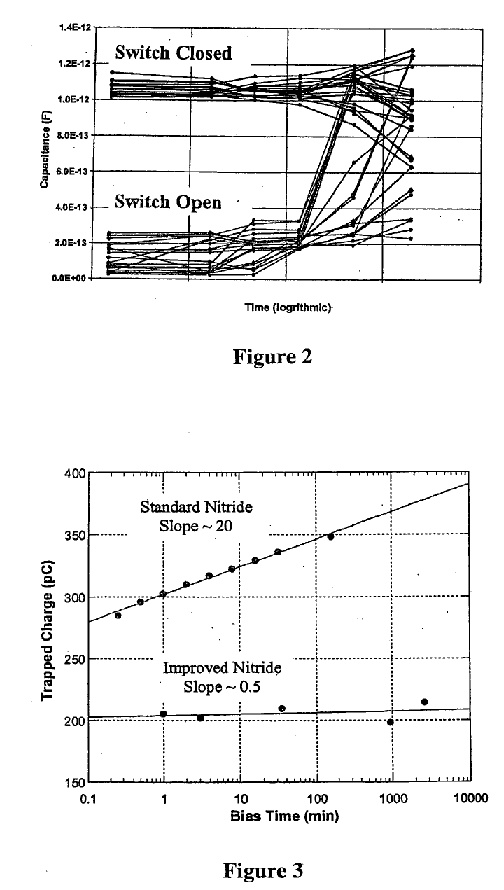

### DETAILED DESCRIPTION OF THE PREFERRED EMBODIMENTS

Trapped charges within a dielectric can be caused by many factors. Detailed capacitance-voltage (C-V) measurements may be conducted on metal-dielectric-semiconductor structures as a means of quantifying the amount of charge trapped in a dielectric film. C-V methods for characterizing dielectrics used in MEMS capacitive switches allow the behavior of the dielectric to be separated from the mechanical, electrical, material, and environmental complications associated with testing a complete MEMS switch. C-V methods allow the bulk and interfacial sheet charging of the dielectric to be separated and establish a rapid and inexpensive technique for surveying dielectrics for various applications.

Dielectric films (i.e., nitrides) currently used in the fabrication of MEMS devices are often deposited by plasma enhanced chemical vapor deposition (PECVD). An exemplary PECVD device that can be used with the present invention is the PlasmaTherm® Model 730 PECVD device, which is manufactured and marketed by PlasmaTherm®. Of course, one skilled in the art will readily understand that different PECVD devices can be used and how to adjust the parameters from device to device to achieve the present invention.

The properties of a deposited film, such as silicon nitride, are controlled through several processing parameters and can be dependent upon the device used to deposit the film. For example, with the Model 730 PECVD device, the following seven process parameters control the deposition of a silicon nitride film: silane (SiH₄) flow rate, ammonia (NH₃) flow, nitrogen (N₂) flow, helium (He) flow, RF power, and deposition chamber pressure and temperature. A method for determining the optimum values for the process parameters associated with depositing a film is described below.

As will be shown in further detail below, it was discovered that the charge trapping characteristics of a nitride can be controlled by controlling the amount of Si:H, Si:Si, and N:H bonds in a nitride. A number of experiments were performed to show the correlation between the Si:H, Si:Si, and N:H bonds in a nitride and charge trapping. Below, the experiments are described and experimental data is reported. One having ordinary skill in the art will readily understand how to achieve the present invention after reviewing the present disclosure.

A metal-insulator-semiconductor (M-I-S) structure including the dielectric was constructed on a silicon wafer with the PECVD device. An exemplary capacitor is shown in FIG. 6. The M-I-S structure 600 includes a silicon wafer 6, which is grounded. A dielectric film 4 is deposited on the wafer 6 by substantially the same process as the dielectric layer 4 for the MEMS device. A capacitive (metal) cap 5 is deposited on the dielectric film 4 at the mask level. The resulting M-I-S structure can then be tested to determine the behavior of the dielectric layer 4, and particularly, the amount of charge that the dielectric is capable of trapping. The behavior of the dielectric layer 4 in the M-I-S structure will correlate to the behavior of the dielectric layer 4 of the MEMS switch.

A bias voltage was applied to the capacitor, and flatband measurements can be taken to quantify the amount of charge trapped in the dielectric. The total charge trapped in the dielectric 4 can be extracted from the flatband voltage (V_{FB}) measurements taken from the C-V curves of the M-I-S structure by the formula:
V_{FB}=Ø_{MS}−(Q_{F}/C_{FB}).

Ø_{MS} is the work function of the metal-semiconductor system, V_{FB} and C_{FB} are the measured flatband voltage and the flatband capacitance of the MIS structure, respectively, used to simulate the electric environment of a nitride dielectric incorporated into a MEMS device. Preferably, the time dependence of the total charge trapped in the dielectric films is measured under a −50 Volt bias.

Using an iterative scientific method, the process parameters used for depositing the dielectric film were incrementally varied. A number of M-I-S structures were created, each with a dielectric layer having different properties. Flatband measurements are taken for each M-I-S structure. The impact of each process parameter on the behavior of the dielectric can be determined based on the measurements, and the process parameters was incrementally varied for each iteration until the amount of trapped charge measured in the dielectric film of the M-I-S structure is minimized.

For example, a thin film measurement system was used to determine the following quantities for the nitride films: thickness (d), refractive index (n), extinction coefficient (k), and energy band gap (E_{g}). An n&k Analyzer was used to obtain these quantities and measures the reflectance spectrum of the nitride and the substrate over optical wavelengths from 190 to 1000 nm. The reflectance spectrum represents the interaction of the light with both the nitride film and the silicon substrate and is dependent, in this case, on the nitride film thickness, refractive index spectra, and the extinction coefficient spectra, as well as the energy band gap of the nitride material. The physical properties of the nitride are extracted from the measured reflectance data using the Forouhi-Bloomer formulation for the dispersion relation of n(λ) and k(λ) and the Fresnel equation to describe the reflectivity of the thin film system. This measurement technique has been used to characterize amorphous and polycrystalline silicon films, carbon overcoats, and Cr—SiOx and SiC thin film resistors.

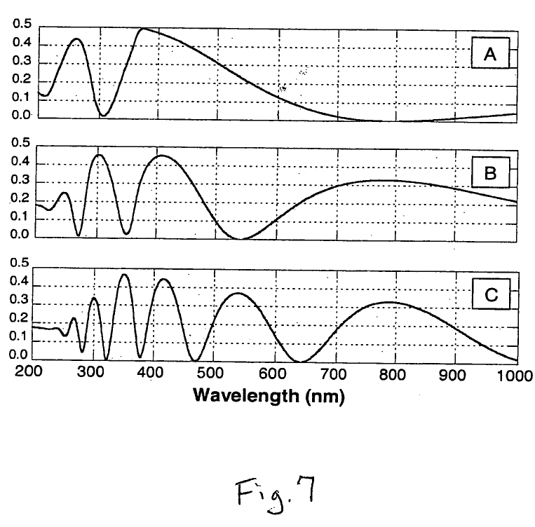

FIG. 7 illustrates the reflectance spectrum for several generic silicon nitride films of varying thickness (e.g., A=1000 Å, B=2000 Å. C=4000 Å). In the case of a single film deposited on a substrate, the peaks in the reflectance spectra tend to become more numerous and more closely spaced as the thickness of the film is increased. This trend is the result of an interference pattern set up by reflections from the top surface of the film and the top surface of the substrate.

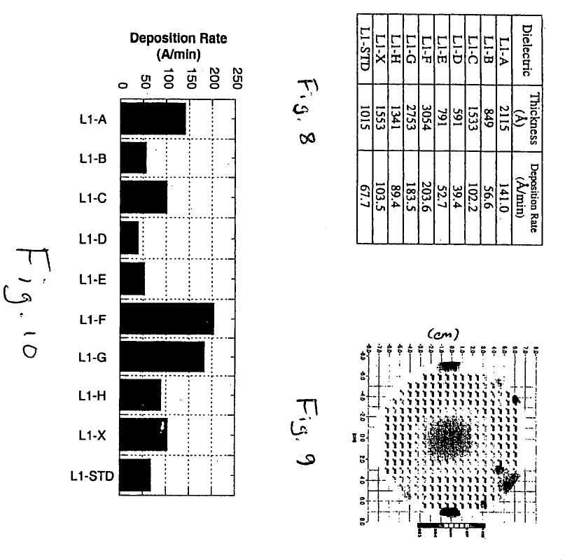

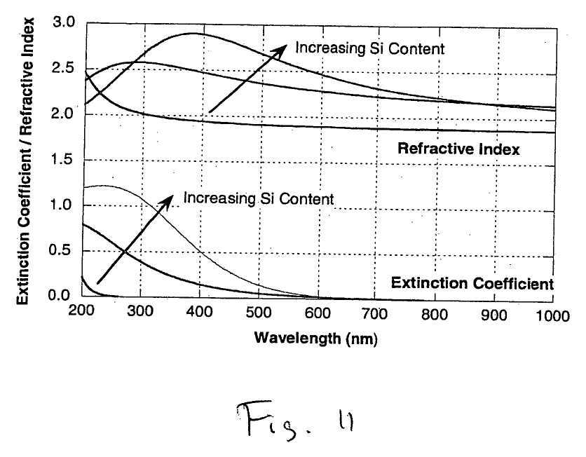

The reflectance spectrum has been used to determine the thickness of silicon nitride films deposited on silicon substrates. FIG. 8 reports the thickness of a number of films obtained from a 15-minute deposition in addition to the deposition rate associated with each process. Also listed in FIG. 8 is the standard deviation (L1-STD) of 256 thickness measurements taken across the face of the 6-inch silicon wafers used. FIG. 9 is an example of the wafer mapping used to measure the nitride thickness across each wafer. This parameter gives an indication of the deposition uniformity for each process.

The n&k Analyzer was used to extract the refractive index and extinction coefficient dispersion curves for each nitride film. The refractive index, n(λ), at 633 nm has traditionally been used as a means of process monitoring to ensure constant composition from lot to lot. The refractive index, however, of PECVD silicon nitrides has been shown to only roughly correlate with the film composition and gives limited information concerning the relative abundance of Si—N, Si—H, N—H, and Si—Si bonding in the film.

FIG. 11 shows the extinction coefficient and the refractive index dispersion curves for three generic silicon nitrides with increasing amounts of silicon incorporated in each film. The refractive index generally seems to increase with silicon content over wavelengths from 400 to 600 nm. However, at wavelengths in the UV (200-400 nm) and the near-IR (800-1000 nm), the refractive index loses much of its sensitivity to variations in silicon content. These changes in refractive index with composition may be a function of both composition and film density—denser films having a higher refractive index.

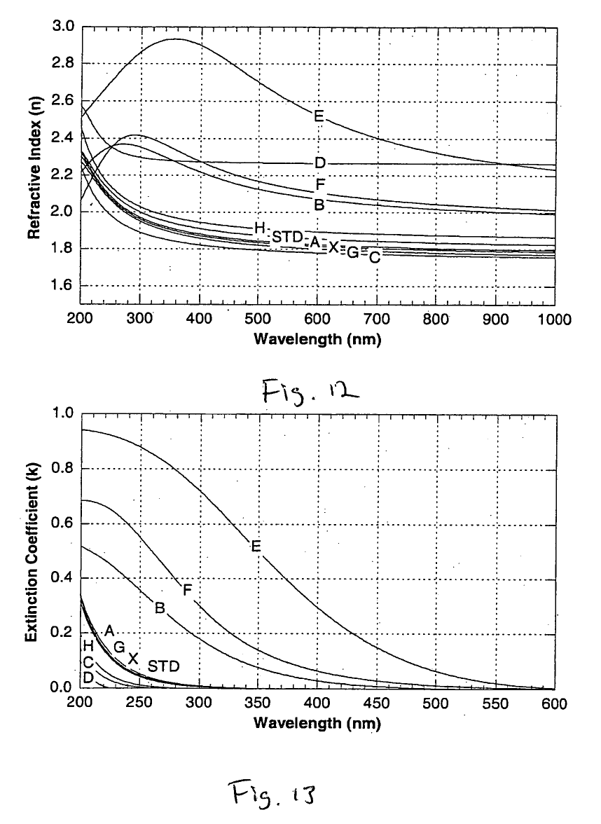

The refractive index dispersion curve for each nitride film outlined in FIG. 16 has been measured and is displayed in FIG. 12, and FIG. 14 compiles the refractive index for each film at 633 nm and 248 nm as well as the standard deviation of these parameters for 256 points measured across each 6 inch wafer. Again, the refractive index data does not lend much insight into the composition of the nitrides other than to provide a quick means for establishing process reproducibility and uniformity.

The behavior of the extinction coefficient shown in FIG. 11 offers some insight into the Si—Si bonding occurring in the nitride film. Of the possible bonds in the nitride film (Si—N, Si—H, N—H, Si—Si, and perhaps SiO), only the Si—Si bonds absorb in the UV wavelength (200-400 nm). As the silicon composition is increased in these films to the extent that dimers and trimers of silicon are formed, the film will begin to show the UV absorption associated with bulk silicon. The impact of increasing Si—Si bonding in a generic nitride is illustrated in FIG. 11 with an increase in the extinction coefficient in the UV. The extinction coefficient dispersion curve for each nitride film outlined in FIG. 9 has been measured.

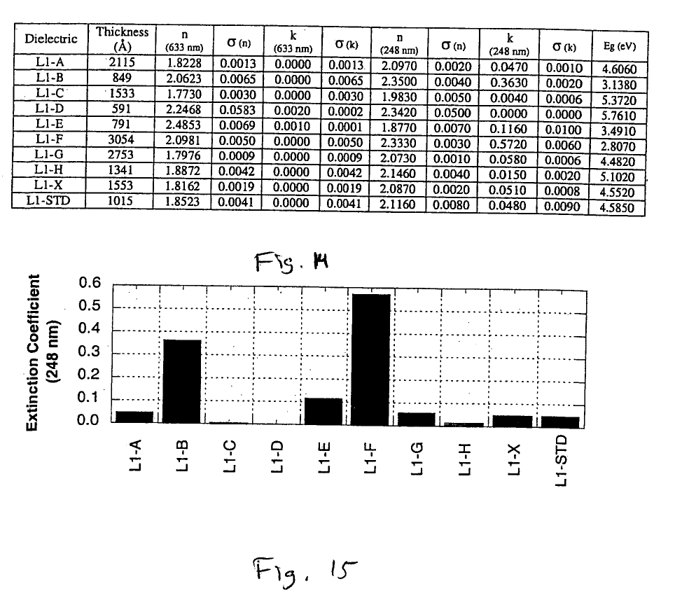

FIG. 13 displays the extinction coefficient dispersion curves graphically for each film, and FIG. 14 compiles extinction coefficient for each film at 633 nm and 248 nm as well as the standard deviation of these parameters for 256 points measured across each 6 inch wafer. As you can see, films H, C, and D have relatively low silicon content relative to films B, F, and E.

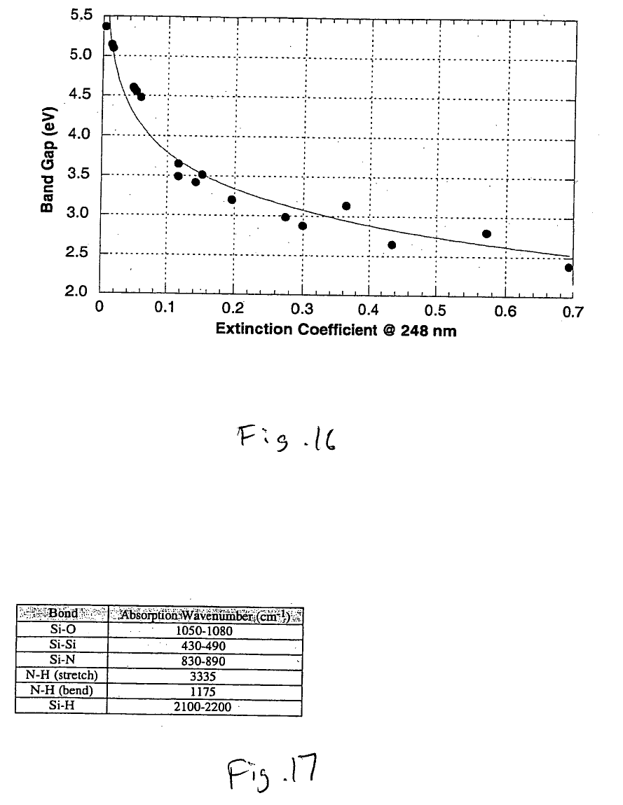

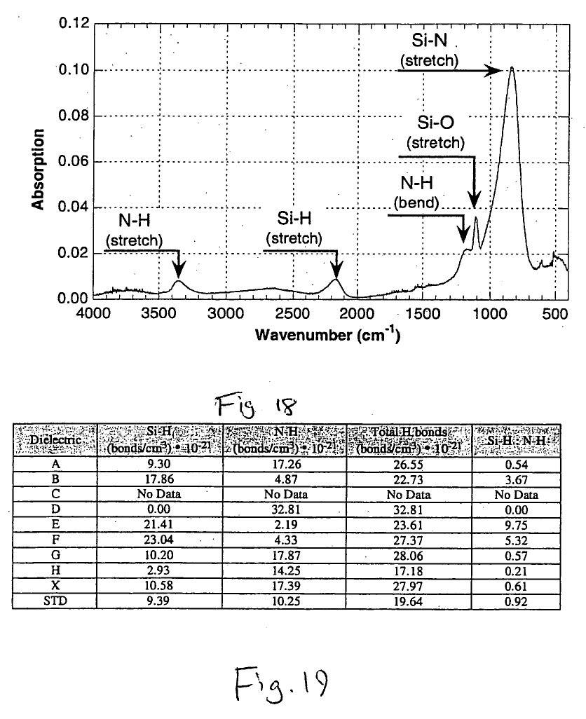

FIG. 15 shows a graphical representation of the extinction coefficient at 248 nm for each nitride process as a more convenient means for comparing the various films. Additional film properties which may have an impact on the UV extinction of these nitrides is the distortion of the nitride lattice which may be the result of excessive strain or hydrogen incorporation in the film leading to strained bond distances and bond angles.

The silicon content of the various nitrides correlates very well with the measured band-gap and conductivity of these films. The band gap, Eg, measured by the n&k Analyzer represents the minimum photon energy required to induce a direct electronic transition from the valence to the conduction band. Note that E=hc/λ, and for the case of E<Eg, absorption of light due to direct electronic transitions does not occur. FIG. 14 compiles the band gap energies measured for each of the nitride films.

FIG. 16 shows the logarithmic correlation between the band gap energy, Eg, and the extinction coefficient at 248 nm, k (248), for the nitrides in this study. This behavior can be related to the composition of the nitride films: the value of the UV extinction coefficient is a measure of the relative abundance of Si—Si bonding in the nitride films, as the Si:Si bonding increases (increasing extinction coefficient) the band gap energy decreases, representing a more conductive film. This behavior has been confirmed through I-V measurements on the films.

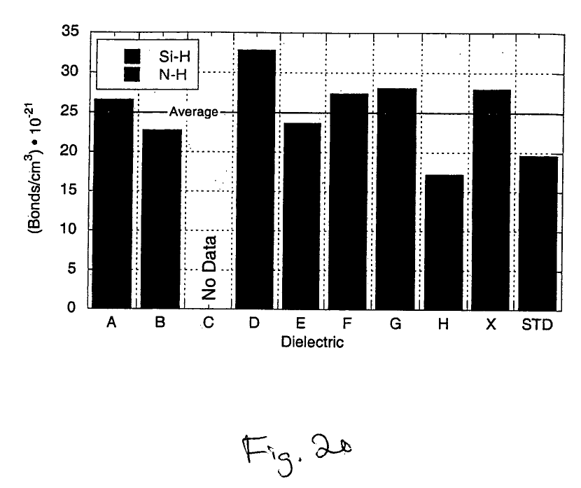

FIG. 18 shows a typical IR spectrum for the “standard” (L1-STD) nitride with the important absorption peaks identified. The areas beneath Si—H absorption peak at 2150 cm⁻¹ and the N—H stretching peak at 3335 cm⁻¹ measure the concentration of bound hydrogen in the nitride films. FIG. 19 summarizes the results of the IR measurements on the nitrides in this study, showing two groups of films: one containing films with large amounts of Si—H bonds relative to N—H bonds, and the other containing small amounts of Si—H bonds relative to N—H bonds. Each film was measured at five points on a six inch wafer, establishing a relatively uniform composition across the substrate.

However, the silicon substrates used for this measurement are not ideal for silicon nitride spectra because of the over lap of bonds (Si—Si, Si—H, and Si—O) existing in the silicon background and bonds existing in the nitride sample. This is particularly evident in measurements on the Si—Si peak at 450 cm⁻¹, which were inconclusive. The Si—N peak proved difficult to measure to get meaningful bond densities because of the large number of bonds that absorb near 850 cm¹, including the N—H stretch, Si—O, and a Si—H mode (not shown).

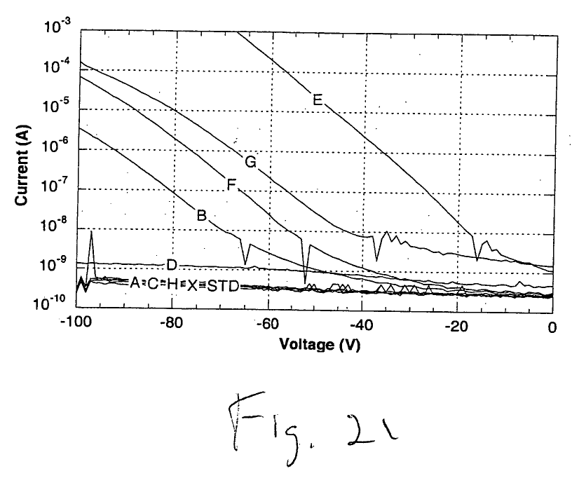

FIG. 20 shows a graphical representation of the bond concentrations for these nitrides, as well as the average value for all these films; again, the total amount of hydrogen bonds remain relatively constant. However, the study did show that the hydrogen could be shifted between Si and N bonds, as shown in FIG. 20 and indicated by the Si—H: Si—N ratio in FIG. 19. Similar behavior has been reported by Lanford and Rand who postulated that the hydrogen content had significant impact of the structural strain of the film as indicated by the etch rate of various nitrides in buffered HE.

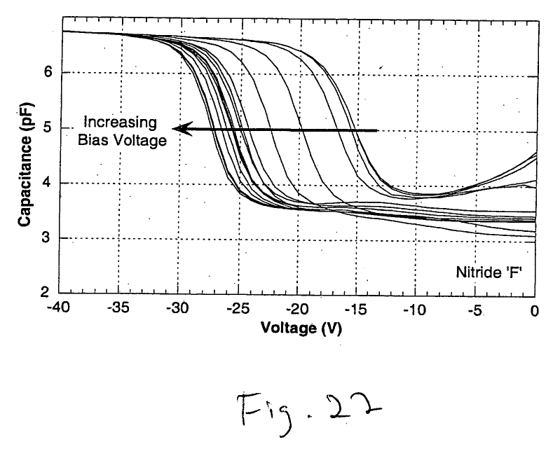

Hysteresis curves were measured between −100 V and +100 V for each nitride film in this study. The structures used for this measurement were metal/insulator/metal fabricated on GaAs wafers with a passivating nitride used to insulate the bottom metal of the MIM from the semiconducting substrate. The nitride film thickness were approximately 2.5 kA for this measurement. FIG. 21 shows the negative voltage lobe (for clarity) I-V sweep for each dielectric. The I-V curve for each nitride shows distinct conduction mechanisms in consecutive voltage ranges. At low voltages the curve follows Ohm's law (Y˜I) and then transitions to Fowler-Nordheim (I˜V² exp(1/v)) and Poole-Frenkel (I˜vsinh(V^{1/2}/kT)) conduction.

The relative conductivities of each film correlate reasonably well with the band gap energy and UV extinction coefficient measurements described earlier. The films having a higher extinction coefficient (see FIG. 15 and therefore a higher abundance of Si—Si bonds also are the more conductive films in the I-V measurements. Note, in particular, that nitrides B, E, and F cover a large range of conductivity in FIG. 21, a trend that is generally mirrored in the bandgap and UV extinction measurements. It is also worthwhile to note that the IR measurements distinguish nitrides B, E, and F as having very high Si—H:N—H bond ratios relative to the other nitrides in this study.

The flatband voltage of each dielectric has also been measured under varying bias conditions. In this set of measurements, the C-V curves were traced from 0 Volts to Vmax, where Vmax was incremented from 5 V to 100 V in 5 volt steps. FIG. 22 illustrates the C-V curves obtained from this procedure. Qualitatively, FIG. 22 shows that the charge trapped in the dielectric increases with increasing bias across the M-I-S structure. For each C-V curve, the flatband voltage is used to quantify the charge trapped in each dielectric as a function of bias.

Detailed capacitance-voltage measurements have been conducted on metal-dielectric-semiconductor (M-I-S) structures as a means of quantifying the charge trapped in stressed nitride films. The impetus behind developing a C-V method of characterizing dielectrics used in MEMS capacitive switches is to separate the behavior of the nitride from the mechanical, electrical, material, and environmental complications associated with testing a complete switch. The C-V measurements offers the opportunity to separate the bulk and interfacial sheet charging of the dielectric as well as establishing a rapid and inexpensive technique for surveying dielectrics for various applications.

In order to quantitatively compare the total trapped charge among the various nitrides, the flatband results must be normalized for constant field strengths across the dielectric. This normalization is accomplished by scaling the bias voltage by the inverse of the nitride thickness: E−V/d.

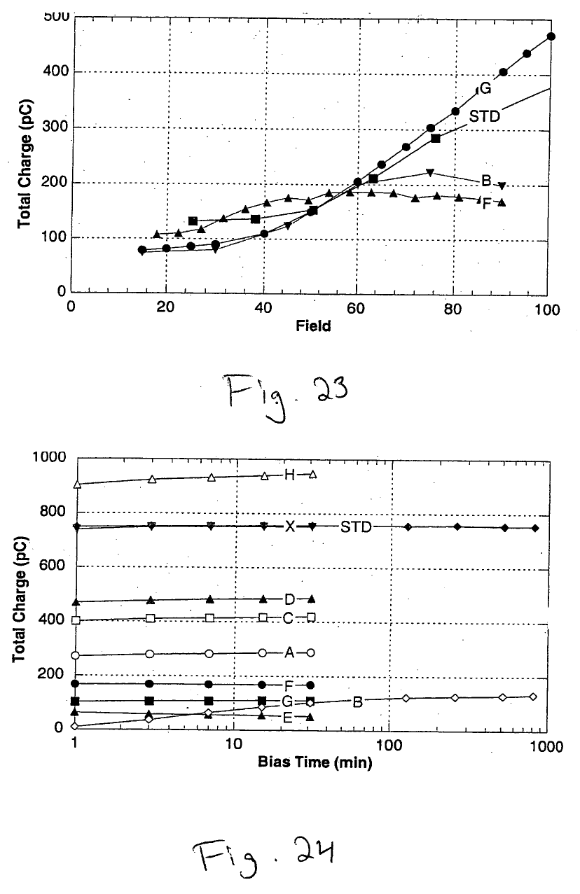

FIG. 23 shows the total trapped charge for several nitrides as a function of field strength. Note that this data shows several distinct charging regimes, just as the I-V sweeps demonstrated: Ohm's law (Q˜E) and then transitions to Fowler-Nordheim (Q−E2 exp(1/V)) and Poole-Frenkel (Q˜E sinh(E^{1/2}/kT)) conduction. The time dependence of the total charge trapped has also been measured. Each dielectric was biased at −50 V and the flatband voltage shift recorded as a function of time. FIG. 24 shows the time dependence of total charge for all the dielectrics developed in this example.

Once the amount of trapped charge in the dielectric is minimized, the process parameters are considered to be optimum. MEMS devices can be fabricated using these optimum process parameters for depositing the dielectric layer 4. FIG. 3 shows the charge accumulated in the standard and improved dielectrics as a function of time.

The charge accumulation data extracted from flatband measurements on M-I-S structures show a significant decrease in charging of the improved dielectric relative to the standard silicon nitride deposition process. The slope of the accumulation curve decreased from ˜20 to ˜0.5. The slope of these curves is proportional to the concentration of trap states in the dielectric based on a model by Buchanan et al. (Solid State Electronics, Vol. 30, No. 12, pp. 1295-1301, 1987, the entire contents of which are incorporated herein by reference).

Buchanan et al. describes a simplified model for depicting charge transfer in and out of traps in the silicon nitride through a tunneling process, which shows that the charge (Q) trapped in the dielectric increases logarithmically with time (t):

$$Q ( t ) ∞ N [ 1 n ( \frac{t}{{t}_{o}} ) + Constant ] .$$

Based on this model, the relative concentration of trap states (N) in a given dielectric can be obtained from the slope of a plot of Q(t) against 1 n(t/tₒ), where tₒ is a constant to make the quantity (t/tₒ) dimensionless. The slopes of the curves shown in FIG. 3 indicate that the concentration of trap states has been reduced by a factor of 40 in the improved dielectric relative to the standard dielectric used in fabricating MEMS capacitive switches.

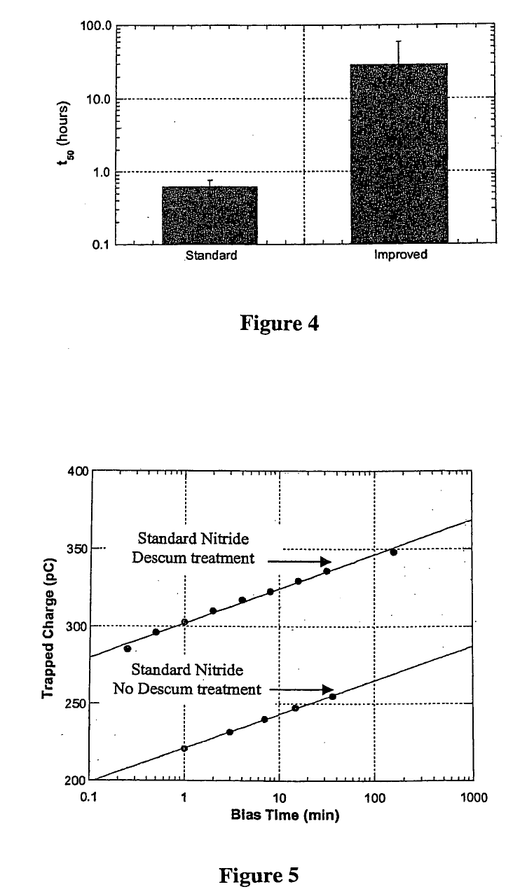

MEMS capacitive switches have been fabricated to demonstrate the improvement in switch performance and reliability based on the use of the improved dielectric. FIG. 4 shows data collected from packaged reliability tests of switches fabricated using the improved silicon nitride dielectric. These data indicate an increase in switch lifetime of 40 times resulting from the use of the improved dielectric. These results correlate well with the improvement seen in the charge accumulation in M-I-S structures.

The flatband data shown in FIG. 3 and the lifetime data shown in FIG. 4 establishes a correlation between the charging data obtain from M-I-S structures and switch reliability. This correlation can be used as a means of monitoring the quality of the nitride through the fabrication process. A silicon wafer can be included for the fabrication of M-I-S structures with each MEMS device fabrication. As described above, the wafer will be processed identically to the device wafers, at least with respect to the deposition of the dielectric layer. At each mask level the silicon wafer will receive a capacitor top deposited on top of the silicon nitride dielectric used for the device lot. C-V measurements will provide a means of monitoring the concentration of trap states in the nitride as the fabrication progresses, identifying specific steps (process parameters) that are hazardous to the dielectric. For example, this structure has been used to establish the impact of an oxygen plasma descum (a process used frequently in MEMS fabrication) on silicon nitride films.

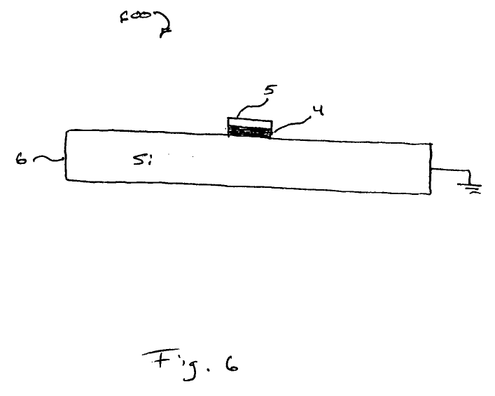

FIG. 5 shows a dramatic increase in trapped charge following an oxygen plasma treatment in the standard silicon nitride dielectric. The nitride receiving the descum process shows a significant increase in the initial trapped charge, however, it continues to accumulate additional charge at the same rate as the untreated nitride. Thus, an oxygen descum process is preferably avoided and a chemical descum process is preferred.

Thus, new and improved dielectric suitable for use in electronic and MEMS devices have been provided herein. Two strong correlations were discovered relative to the observed molecular bonding and the charging behavior of the resulting nitrides. Desirable low charging behavior of a nitride corresponds with a high number of Si:Si bonding (demonstrated by the extinction coefficient measurements taken using 248 nm light), as well as a large ratio of Si:H bonds compared to N:H bonds. However, there is more than one possible explanation for why an increase in Si:Si bonds and a large Si:H/N:H ratio would cause the improved (i.e., decreased) charging behavior in the nitrides. Improved nitrides had Si:H/N:H ratios greater than 1, and preferably greater than 3 (e.g., three test nitrides that had good performance had ratios of 3.67, 9.75, 5.32 respectively). The extinction coefficients for improved nitrides measured at 248 nm (which correlates to Si:Si bonding) were greater than 0.06 and preferably greater than 0.1 (e.g., three test nitrides that had good performance had extinction coefficients of 0.363, 0.116 and 0.572 respectively). No poor performing nitrides were determined to have an Si:H/N:H ratio's greater than 1, or extinction coefficients at 248 nm greater than 0.06.

Thus, a number of preferred embodiments have been fully described above with reference to the drawing figures. Although the invention has been described based upon these preferred embodiments, it would be apparent to those of skilled in the art that certain modifications, variations, and alternative constructions would be apparent, while remaining within the spirit and scope of the invention.

We claim:

1. An improved dielectric comprising:
silicon nitride having a percentage of Si—H bonds greater than a percentage of N—H bonds.

2. The improved dielectric of claim 1 wherein a ratio of Si—H bonds to N—H bonds in said silicon nitride exceeds 1:1.

3. The improved dielectric of claim 1 wherein a ratio of Si—H bonds to N—H bonds in said silicon nitride exceeds 3:1.

4. The improved dielectric of claim 1 wherein an extinction coefficient of said dielectric exceeds 0.06.

5. The improved dielectric of claim 1 wherein an extinction coefficient of said dielectric exceeds 0.1.

6. A micro-electro-mechanical system (MEMS) device comprising:
an electrode; and
a dielectric film deposited on the electrode, said dielectric film comprising silicon nitride having an amount of Si—H bonds that exceeds an amount of N—H bonds.

7. The MEMS device of claim 6, wherein a ratio of Si—H bonds to N—H bonds in said dielectric film exceeds 1:1.

8. The MEMS device of claim 6, wherein a ratio of Si—H bonds to N—H bonds in said dielectric film exceeds 3:1.

9. The MEMS device of claim 6, wherein an extinction coefficient of said dielectric film exceeds 0.06.

10. The MEMS device of claim 6, wherein an extinction coefficient of said dielectric film exceeds 0.1.

11. A method of fabricating an improved dielectric, comprising:
depositing silicon nitride by plasma enhanced chemical vapor deposition, wherein N—H bonds in said silicon nitride are shift to Si—H bonds in order to reduce charge trapping capability of said dielectric.

12. The method of claim 11, wherein silicon nitride is deposited such that a ratio of Si—H bonds to N—H bonds in said dielectric film exceeds 1:1.

13. The method of claim 11, wherein silicon nitride is deposited such that a ratio of Si—H bonds to N—H bonds in said dielectric film exceeds 3:1.

14. The method of claim 11, wherein silicon nitride is deposited such that an extinction coefficient of said dielectric film exceeds 0.06.

15. The method of claim 11, wherein silicon nitride is deposited such that an extinction coefficient of said dielectric film exceeds 0.1.

16. A method of optimizing fabrication of a micro-electromechanical (MEMS) device, comprising the steps of:
(a) depositing a dielectric film on a test structure under similar conditions as said dielectric film would be deposited on an electrode of said MEMS device;
(b) determining an amount of trapped charge within said deposited dielectric film;
(c) adjusting at least one process parameter of said depositing step (a) in order to reduce the amount of trapped charge within said dielectric film;
(d) repeating steps (a)-(c) until the amount of trapped charge within said dielectric film has been minimized; and (e) thereafter using said adjusted process parameters to fabricate said MEMS device.

17. The method of claim 16, wherein said depositing step (a) comprises plasma-enhanced chemical vapor deposition.

18. The method of claim 16, wherein said at least one process parameter includes silane flow rate.

19. The method of claim 16, wherein said at least one process parameter includes ammonia flow rate.

20. The method of claim 16, wherein said at least one process parameter includes nitrogen flow rate.

21. The method of claim 16, wherein said at least one process parameter includes helium flow rate.

22. The method of claim 16, wherein said at least one process parameter includes a chamber pressure of the deposition chamber of the deposition device used in said deposition step.

23. The method of claim 16, wherein said at least one process parameter includes a chamber temperature of the deposition chamber of the deposition device used in said deposition step.

24. The method of claim 16, wherein said at least one process parameter includes a radio-frequency power of the deposition device used in said deposition step.

25. The method of claim 16, further comprising:
fabricating a metal-insulator-semiconductor (MIS) structure;
measuring flatband voltage of the MIS structure; and
wherein said determining step includes calculating a total charge trapped in said dielectric film based on said flatband voltage measured.

26. The method of claim 25, wherein said metal-insulator-semiconductor structure is a capacitor deposited on said dielectric film.

27. A method of determining an amount of trapped charge in a dielectric film of a micro-electromechanical (MEMS) device fabricated in accordance with a plurality of specific process conditions, comprising steps of:
depositing a dielectric film on a silicon wafer, said dielectric film being deposited under the same conditions as said dielectric film of said MEMS device;
depositing a metal layer on top of said dielectric film;
biasing the structure created by said metal layer and said dielectric film with a bias voltage;
measuring a flatband voltage and a flatband capacitance of said structure; and
calculating an amount of trapped charge based on said flatband voltage and flatband capacitance measured.

28. The method of claim 27, wherein each of said steps are repeated for a plurality of iterations, and wherein at least one process parameter related to said depositing step is varied for each iteration.

29. The method of claim 28, wherein said at least one process parameter includes silane flow rate.

30. The method of claim 28, wherein said at least one process parameter includes ammonia flow rate.

31. The method of claim 28, wherein said at least one process parameter includes nitrogen flow rate.

32. The method of claim 27, wherein said at least one process parameter includes helium flow rate.

33. The method of claim 27, wherein said at least one process parameter includes a chamber pressure of the deposition chamber of the deposition device used in said deposition step.

34. The method of claim 27, wherein said at least one process parameter includes a chamber temperature of the deposition chamber of the deposition device used in said deposition step.

35. The method of claim 27, wherein said at least one process parameter includes a radio-frequency power of the deposition device used in said deposition step.

36. The method of claim 27, wherein each iteration is performed until said amount of trapped charge is minimized.

37. A MEMS device having a dielectric film deposited on an electrode of said MEMS device, said dielectric film being deposited with a plasma enhanced chemical vapor deposition process wherein process parameters relating to depositing said dielectric film with said plasma enhanced chemical vapor deposition process are selected via the method claimed in claim 21.

38. The MEMS device of claim 31, wherein said dielectric film is silicon nitride.

39. A method of fabricating a capacitive MEMS switch having a dielectric film, comprising:
a step for fabricating a M-I-S structure on a dielectric film;
a step for determining an amount of trapped charge in said dielectric film of said MIS structure;
a step for determining optimum process parameters associated with depositing said dielectric film to minimize the amount of trapped charge in said dielectric film as determined by said trapped charge amount determining step; and
a step for fabricating said MEMS switch utilizing said optimum process parameters to deposit said dielectric film.
